(19) United States
(12) Patent Application Publication
(10) Pub. No.: US 2025/0217562 A1
(43) Pub. Date: Jul. 3, 2025

(54) METHOD OF PREDICTING SEMICONDUCTOR DEVICE FAILURE RATE AND AN ELECTRONIC DEVICE FOR PERFORMING THE SAME

(71) Applicant: SAMSUNG ELECTRONICS CO., LTD., Suwon-si (KR)

(72) Inventors: JaeHong Kim, Suwon-si (KR); Hyein Lee, Suwon-si (KR); Hyein Lim, Suwon-si (KR); Se-Young Kim, Suwon-si (KR); Seongjin Mun, Suwon-si (KR)

(21) Appl. No.: 18/830,434

(22) Filed: Sep. 10, 2024

(30) Foreign Application Priority Data
Dec. 29, 2023 (KR) 10-2023-0197155

(51) Int. Cl. G06F 30/3308; G06F 30/31

(52) U.S. Cl. CPC G06F 30/3308; G06F 30/31

(57) ABSTRACT

A method of predicting semiconductor device failure rate and an electronic device for performing the method are provided. The method of predicting semiconductor device failure rate includes receiving schematic data for a unit circuit in a first circuit and layout data corresponding to the schematic data, generating, by at least one processor, a netlist based on the schematic data and the layout data, performing a first simulation on the layout data to generate first simulation data for a test point of the layout data corresponding to a first node in the netlist, applying the first simulation data to a second simulation for the first node to generate second simulation data regarding whether the unit circuit is in fail operation, and calculating a failure rate for the first circuit based on the second simulation data.

### CROSS-REFERENCE TO RELATED APPLICATION

This application claims priority to and the benefit of Korean Patent Application No. 10-2023-0197155 filed in the Korean Intellectual Property Office on Dec. 29, 2023, the entire contents of which are incorporated herein by reference.

### BACKGROUND OF THE INVENTION

In recent years, remarkable progress has been made with the degree of integration of semiconductor devices, such as dynamic random access memory (DRAM) and static random access memory (SRAM). Concurrent with the high integration of semiconductor device in these years, is a trend for reduction in size of a memory cell. With this reduction in size, the electrostatic capacitance becomes smaller, making it increasingly difficult to maintain high reliability against soft errors, which are generally caused by alpha rays, neutron beams or the like.

Here, the term “soft error” means information stored in a memory cell is inverted. For example, charges generated in a semiconductor memory device due to alpha rays, neutron beams or the like may be collected in a storage node (a diffusion layer part to hold data), under the influence of an electric field substantially generated at the PN junction. A phenomenon that information written to a memory cell is reversed and rewritten due to the above charge collection phenomenon may be referred to as a soft error. In addition, an error (event) caused by the incidence of one particle, such as an ion or a neutron, into the semiconductor device, is referred to as “SEE (Single Event Effect)”.

Although the soft error is a temporary phenomenon, a soft error can cause significant data errors in circuits where column or row addresses are latched.

### SUMMARY OF THE INVENTION

The present disclosure provides a method of predicting a semiconductor device failure rate that predicts, e.g., precisely predicts, a failure rate for data inversion and an electronic device for performing the method.

The present disclosure provides a method of predicting semiconductor device failure rate that predicts, e.g., precisely predicts, a failure rate for a repair operation and an electronic device for performing the method.

In a general aspect, a method of predicting semiconductor device failure rate includes: receiving schematic data for a unit circuit in a first circuit and layout data corresponding to the schematic data, generating, by at least one processor, a netlist based on the schematic data and the layout data, performing a first simulation on the layout data to generate first simulation data for a test point of the layout data corresponding to a first node in the netlist, applying the first simulation data to a second simulation for the first node to generate second simulation data regarding whether the unit circuit is in fail operation, and calculating a failure rate for the first circuit based on the second simulation data.

In another general aspect, a method of predicting semiconductor device failure rate includes receiving schematic data for a unit latch circuit among a plurality of latch circuits in a row decoder for a memory cell array and layout data corresponding to the schematic data, performing a first simulation of injecting high-energy particles into a partial region in the layout data of the unit latch circuit, generating first simulation data for a noise current detected at a test point of the layout data corresponding to an output node of the unit latch circuit according to the first simulation, performing a second simulation by applying the first simulation data to the output node, generating second simulation data by checking whether a bit flip occurs in the unit latch circuit according to the second simulation, calculating a cross-sectional area of a partial region causing a bit flip in the unit latch circuit based on the second simulation data, and calculating a failure rate for the row decoder based on the cross-sectional area.

In another general aspect, an electronic device includes a user interface device, a processor; and a memory configured to store instructions executable by the processor, wherein the processor is further configured to execute the instructions to receive schematic data for a first circuit and layout data corresponding to the schematic data, perform a first simulation on a test point of the layout data corresponding to a node in the first circuit to store first simulation data, apply the first simulation data to a second simulation of the schematic data to generate a second simulation data regarding whether the second simulation fails, and calculate a failure rate for the first circuit based on the second simulation data.

### BRIEF DESCRIPTION OF THE DRAWINGS

FIG. 1 is a block diagram illustrating an example of an electronic device that performs a method of predicting semiconductor device failure rate.

FIG. 2 is a diagram illustrating an example of a schematic simulation tool.

FIG. 3 is a diagram illustrating an example of a design simulation tool.

FIG. 4 is a flowchart illustrating an example of a method of predicting semiconductor device failure rate.

FIG. 5 is a flowchart illustrating an example of a method of predicting semiconductor device failure rate.

FIGS. 6 to 14 are diagrams illustrating an example of a method of predicting semiconductor device failure rate.

FIG. 15 is a block diagram illustrating an example of an electronic device.

FIG. 16 is a flowchart illustrating an example of a method of predicting semiconductor device failure rate.

FIG. 17 is a block diagram illustrating an example of a computing system that performs a method of predicting semiconductor device failure rate.

### DETAILED DESCRIPTION

Hereinafter, the present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

In addition, unless explicitly described to the contrary, the word “comprise”, and variations such as “comprises” or “comprising”, will be understood to imply the inclusion of stated elements but not the exclusion of any other elements.

Additionally, specific numbers described in a claim, even if explicitly recited within the claim, should not be construed as limiting the specific number in claims where such citation does not exist. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

Furthermore, in those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

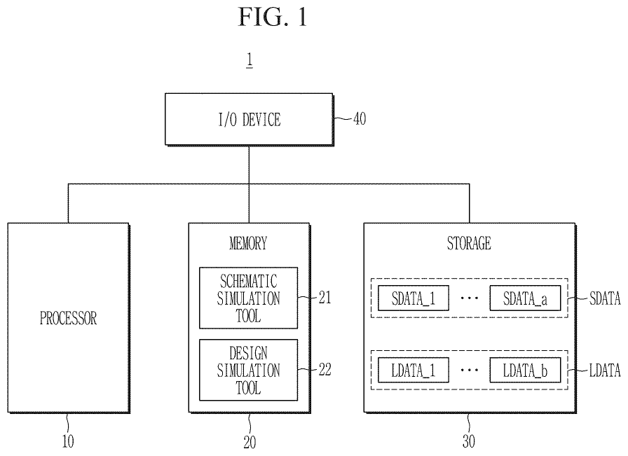

In an embodiment, ‘a module’, ‘a unit’, or ‘a part’ perform at least one function or operation, and may be realized as hardware, such as a processor or integrated circuit, software that is executed by a processor, or a combination thereof. FIG. 1 is a block diagram illustrating an example of an electronic device that performs a method of predicting semiconductor device failure rate.

Referring to FIG. 1, an electronic device 1 may be defined as a system that performs various functions. For example, the electronic device 1 may be a computer-based simulation system, which receives data about unit circuits configuring circuits in a semiconductor device and various information related to simulation processing, outputs simulation results, and predicts the semiconductor device failure rate based on the simulation results.

Hereinafter, a unit circuit is a circuit that performs functions necessary for data input and output and may be a unit cell in which a transistor that implements at least one logic is formed. For example, the unit circuit may input and output 1-bit of data, and the unit circuit may be a memory cell such as SRAM, DRAM, NAND, NOR, or a latch circuit including a latch, a flip-flop, etc., but is not limited thereto.

The electronic device 1 may execute different types of simulation tools. The electronic device 1 may perform a simulation on at least one of the schematic data SDATA and layout data LDATA for a unit circuit based on a simulation tool and apply the results of the simulation to another simulation to predict the semiconductor device failure rate.

Schematic data SDATA may include a plurality of schematic data SDATA_1-SDATA_a. The plurality of schematic data SDATA_1-SDATA_a may vary depending on the type of unit circuit, but is not limited thereto.

In some implementations, schematic data SDATA may include circuit design information about circuit elements in a unit circuit and connection relationships thereof. In some implementations, schematic data SDATA may be generated from RTL code using a standard cell library and may be a gate-level netlist.

Layout data LDATA may include a plurality of layout data LDATA_1-LDATA_b. A plurality of layout data LDATA_1-LDATA_b may correspond to a plurality of schematic data SDATA_1-SDATA_a. Layout data LDATA may include patterns such as material layers, e.g., conductive layers, semiconductor layers, and insulating layers corresponding to each circuit element included in the schematic data SDATA, and arrangement information of the patterns. In some implementations, the layout data LDATA may be data in a graphic design system (GDS) format, but the layout data LDATA is not limited thereto.

In some implementations, the electronic device 1 may be a dedicated device for designing semiconductor devices, a computer for running various simulation tools or design tools, or both. The electronic device 1 may be a stationary computing system, such as a desktop computer, workstation, server, etc., or a portable computing system, such as a laptop computer.

The electronic device 1 may include a processor 10, a memory 20, a storage device 30, and an input/output device 40. The processor 10 may include a calculation circuit. The processor 10, memory 20, storage device 30, and input/output device 40 may be connected to each other through a bus, and the processor 10 may control the memory 20, storage device 30, and input/output device 40.

The processor 10 may execute heterogeneous simulations. In some implementations, the processor 10 may execute a schematic simulation tool 21 and a design simulation tool 22. The processor 10 may execute the schematic simulation tool 21 and the design simulation tool 22 to perform various processing operations related to simulation.

The processor 10 may be at least one of processors such as a central processing unit (CPU), graphics processing (GPU), neural processing unit (NPU), and data processing unit (DPU), or a combination thereof. In some implementations, the processor 10 may include a single core processor or a multi-core processor.

In some implementations, the processor 10 may receive schematic data SDATA for the circuit and layout data LDATA corresponding to the schematic data SDATA. The processor 10 may execute the schematic simulation tool 21 to generate a netlist for schematic data SDATA in which layout data LDATA is reflected and/or perform simulation on the netlist.

The netlist may include connection relationships such as wiring connecting circuit elements included in the designed circuit, connection relationships between functional blocks composed of circuit elements, and node information according to the connection of circuit elements. The structure of the circuit is obtained through the netlist, and the netlist may reflect parasitic components according to the circuit connection relationship.

In some implementations, the processor 10 may receive simulation data and apply the simulation data to simulation of the netlist. In some implementations, the processor 10 may check whether a unit circuit fails when applying the simulation. For example, the processor 10 may apply one simulation data to the simulation of a unit latch circuit, and the processor 10 may check whether 1-bit data latched in the unit latch circuit fails (bit flips).

In some implementations, the processor 10 may receive layout data LDATA_1-LDATA_b for the circuit, and execute the design simulation tool 22 to perform semiconductor device modeling or operation simulation for the semiconductor device on the layout data LDATA_1-LDATA_b.

The semiconductor device modeling may be performed through physically-based thin film deposition process simulation and etching process simulation based on layout data LDATA_1-LDATA_b, and the modeled semiconductor device may be implemented.

Here, semiconductor device modeling refers to the structure, such as the arrangement of each component that makes up the semiconductor device, and the values of each component of the semiconductor device has (for example, the thickness of the thin film, the depth of the part removed through the etching process, the physical properties of the included materials, etc.), and may also be referred to as a target “spec,” e.g., target specifications.

The numerical values of each component can mean fixed constants, mean process variables that can be selected or changed in physically-based thin film deposition process simulation and etching process simulation, or a combination thereof.

In the operation simulation of the semiconductor device, the processor 10 may simulate not only the electrical characteristics but also the mechanical and physical characteristics of the semiconductor device. The results of the simulation may also be used as input for device simulation or device-circuit integrated simulation. During the integrated simulation of process-device-circuit characteristics, the target of the device may be a single device or a plurality of devices.

In some implementations, the processor 10 may inject high-energy particles into a partial region of the layout for the circuit and perform a simulation for the electrical characteristics at a specific node. For example, the processor 10 may inject high-energy particles into a partial region in the layout and generate a transient trend of noise current generated at a specific node based on the injection as simulation data.

The high-energy particles may include, but are not limited to, at least one of X-rays, gamma rays, energetic electrons, protons, and neutrons.

The processor 10 may calculate the area of a partial region corresponding to a certain condition in the layout of the circuit. For example, the processor 10 may perform a simulation of injecting high-energy particles into a partial region of the layout for a unit latch circuit and may calculate the cross-sectional area of the partial region where a fail (bit flip) of the unit latch circuit occurs due to the injection of the high-energy particles. In some implementations, the processor 10 may calculate the cross-sectional area ratio, which is the ratio of the total area of the unit latch circuit to the cross-sectional area.

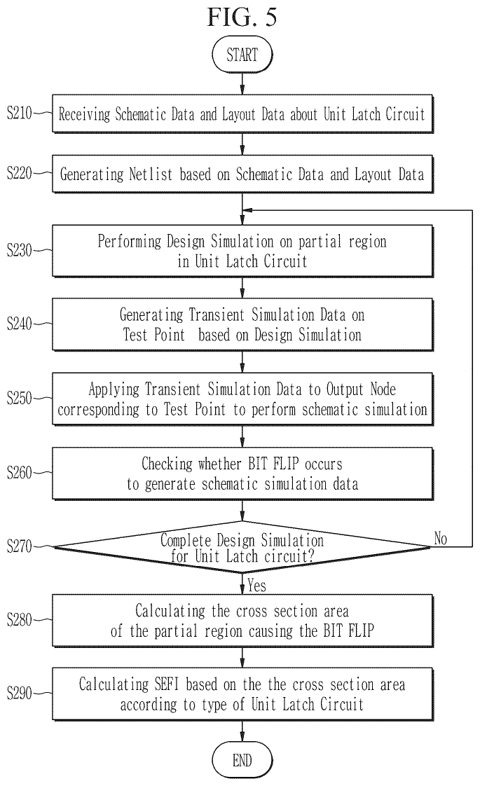

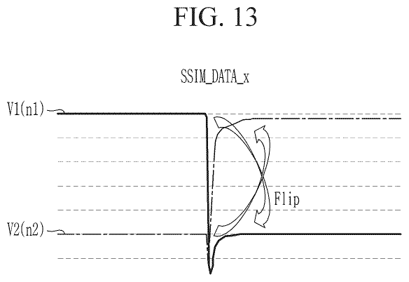

The processor 10 may calculate the failure rate of the circuit according to the type of unit circuit and the cross-sectional area according to the type. In some implementations, the processor 10 may calculate the failure rate of the circuit in the form of single event functional interruption (SEFI), a type of SEE. In some implementations, the processor 10 may calculate the failure rate of the circuit according to a predetermined equation. A description of the above equation will be provided later in the description of FIGS. 5 to 14.

The memory 20 may be used as the main memory or system memory of the electronic device 1. The schematic simulation tool 21 and the design simulation tool 22 executed on the processor 10 may be loaded into the memory 20. The memory 20 may store various information used in simulation operations and calculation operations and may store simulation results and calculation results. The processor 10 may perform various operations by executing the schematic simulation tool 21 and the design simulation tool 22 stored in the memory 20.

The memory 20 may include volatile memory devices such as DRAM, synchronous DRAM (SDRAM), double data rate SDRAM (DDR SDRAM), low power double data rate SDRAM (LPDDR SDRAM), graphics double data rate SDRAM (GDDR SDRAM), DDR2 SDRAM, DDR3 SDRAM, DDR4 SDRAM, DDR5 SDRAM, or the like. Additionally, in some implementations, the memory 20 may include not only a DRAM device but also non-volatile memory such as PRAM, SRAM, MRAM, RRAM, FRAM, Hybrid RAM, or NAND flash.

The storage device 30 may store schematic data SDATA and layout data LDATA. The storage device 30 may store program codes (e.g., computer-readable program codes) for executing the schematic simulation tool 21 and the design simulation tool 22.

The storage device 30 may include a non-volatile memory device and a non-volatile memory controller for the non-volatile memory device. For example, the non-volatile memory device may include a hard drive, optical memory, NAND flash memory, or the like. In some implementations, the storage device 30 may include non-volatile memory, volatile memory, and a combination or part thereof, one of which may be referred to as a “storage medium.”

In some implementations, a non-volatile memory device may be configured to store data in a semi-permanent or substantially permanent form.

The input/output device 40 may include, for example, input devices such as a keyboard, operation panel, or various data reading devices, and output devices such as a monitor, printer, and recording device.

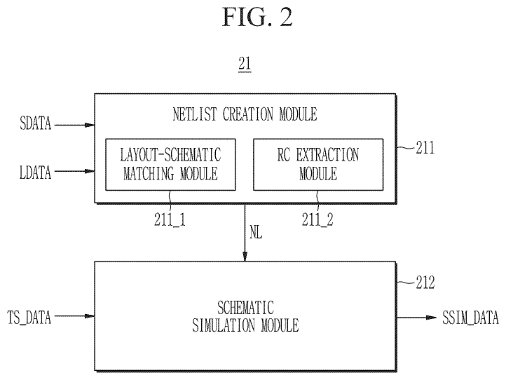

FIG. 2 is a diagram illustrating an example of a schematic simulation tool.

Referring to FIG. 2, the schematic simulation tool 21 may include a netlist creation module 211 and a schematic simulation module 212. The schematic simulation tool 21 may be implemented as an integrated circuit by arranging a plurality of circuits and circuit elements. The schematic simulation tool 21 may verify the operation of the implemented integrated circuit using a simulation tool. In some implementations, the schematic simulation tool 21 may be a simulation program with integrated circuit emphasis (SPICE) simulation tool, but the schematic simulation tool 21 is not limited thereto.

The netlist creation module 211 may receive schematic data SDATA and layout data LDATA and provide a netlist NL corresponding to the actual circuit design. The netlist creation module 211 may include a layout-schematic matching module 211_1 and an RC component extraction module 211_2.

The layout-schematic matching module 2111 may check whether the arrangement in the layout data LDATA and the circuit design in the schematic data LDATA are created identically. The above inspection operation may be referred to as Layout Versus Schematic.

The RC component extraction module 2112 may extract parasitic resistance and parasitic capacitance of connecting wires, which greatly affect the performance of the unit circuit, from the layout data LDATA corresponding to the schematic data SDATA and may model the extracted components.

Depending on the extracted components, the netlist NL may be created by modifying the information in the schematic data LDATA.

The schematic data LDATA and the netlist NL may have some differences in resistive components and capacitive components. In some implementations, the schematic data LDATA and the netlist NL may contain the same information.

The schematic simulation module 212 may perform schematic simulation based on the netlist NL and transient simulation data TS_DATA and output schematic simulation data SSIM_DATA. Schematic simulation data SSIM_DATA may include verification results when applying transient simulation data TS_DATA to a circuit implemented with the netlist NL.

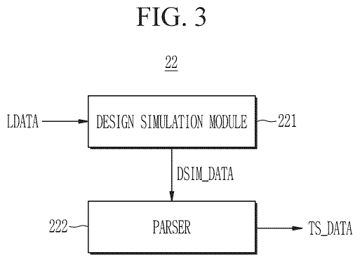

Transient simulation data TS_DATA may be provided in the design simulation tool 22 of FIG. 3. In some implementations, the transient simulation data TS_DATA may include transient information about electrical characteristics at a specific node, and the transient simulation data TS_DATA may be temporary transient information, such as noise current/voltage or fluke voltage, but is not limited thereto.

In some implementations, the schematic simulation module 212 may perform a simulation that applies transient simulation data TS_DATA to a node in the netlist NL and may generate schematic simulation data SSIM_DATA regarding whether the netlist NL is in fail operation by the simulation performance.

In some implementations, the schematic simulation module 212 may perform simulation by applying noise current to the input/output node of the unit latch circuit, and according to the simulation results, the schematic simulation module 212 may generate schematic simulation data SSIM_DATA regarding whether a bit flip occurs in the unit latch circuit.

FIG. 3 is a diagram illustrating an example of a design simulation tool.

Referring to FIG. 3, the design simulation tool 22 may include a design simulation module 221 and a parser 222. The design simulation tool 22 may perform semiconductor device modeling, which is a design simulation, based on layout data LDATA. The design simulation tool 22 may be a technology computer aided design (TCAD) simulation tool.

For semiconductor device modeling, for example, process TCAD, which models the manufacturing process of a semiconductor device, may be used, but is not limited thereto, and device TCAD, which models the operation of a semiconductor device, may also be used. For example, a TCAD tool to perform TCAD may be Synopsys, Silvaco, Crosslight, Cogenda Software|VisualTCAD, Global TCAD Solutions, or Tiberlab, or the like.

In some implementations, the design simulation module 221 may perform motion simulation corresponding to injection of high-energy particles. The design simulation module 221 may detect electrical characteristics at a point in the layout data LDATA through the operation simulation. The electrical characteristics may include voltage, current, resistance characteristics, charge mobility, trap, charge, epsilon, resistance, field, etc. In some implementations, the design simulation module 221 may generate design simulation data DSIM_DATA at one point in the layout data LDATA through the electrical characteristics. In some implementations, the design simulation data DSIM_DATA may include noise current/voltage or fluke voltage, but the design simulation data DSIM_DATA is not limited thereto.

For example, the design simulation module 221 may perform an operation simulation of injecting high-energy particles into a partial region in the layout of the layout data LDATA. Based on the operation simulation, the design simulation module 221 may detect noise current at a test point of the layout data LDATA corresponding to the input/output node of the schematic data SDATA in FIG. 2.

The parser 222 may generate transient simulation data TS_DATA by parsing design simulation data DSIM_DATA. The generated transient simulation data TS_DATA may be provided to the schematic simulation tool 21 of FIG. 2. In some implementations, the generated transient simulation data TS_DATA may be stored in the storage device 30 of FIG. 1.

Transient simulation data TS_DATA may include transient information about electrical characteristics at a point in the layout data LDATA. In some implementations, the transient simulation data TS_DATA may include transient information about drain current, drain voltage, drain current, and gate voltage. In some implementations, the transient simulation data TS_DATA may be noise current/voltage or fluke voltage, which is temporary transient information, but is not limited thereto.

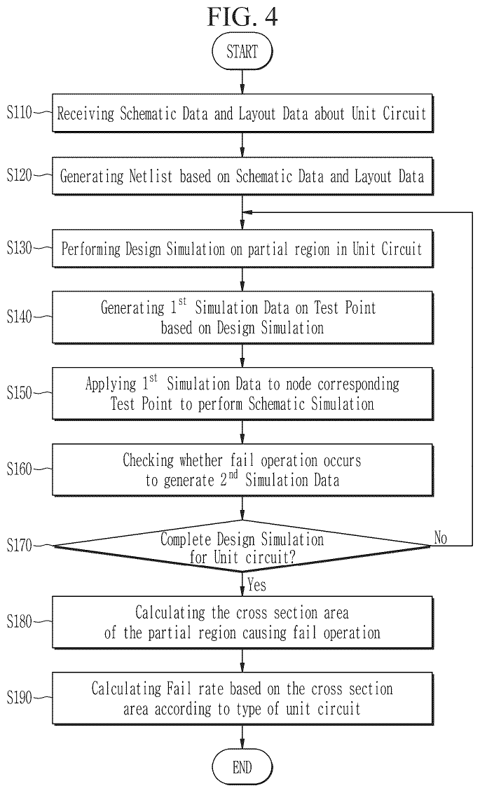

FIG. 4 is a flowchart illustrating an example of a method of predicting semiconductor device failure rate.

Referring to FIGS. 1 to 4, the schematic simulation tool 21 receives schematic data SDATA and layout data LDATA corresponding to the schematic data SDATA (S110).

The schematic simulation tool 21 may receive schematic data SDATA stored in the storage device 30. The schematic simulation tool 21 may receive layout data LDATA corresponding to schematic data SDATA stored in the storage device 30.

Likewise, the design simulation tool 22 may receive layout data LDATA input to the schematic simulation tool 21.

In some implementations, layout data LDATA may be generated based on schematic data SDATA, but the layout data LDATA is not limited thereto.

The schematic simulation tool 21 generates the netlist NL based on schematic data SDATA and layout data LDATA (S120).

In some implementations, the netlist NL may reflect the parasitic resistance and parasitic capacitance of the connecting wires in the layout data LDATA based on the schematic data SDATA.

The design simulation tool 22 performs a design simulation on the partial region based on layout data LDATA (S130).

In some implementations, the design simulation tool 22 may use the design simulation module 221 to perform an operation simulation corresponding to the injection of high-energy particles into a partial region in the layout data LDATA. The high-energy particles may include, but are not limited to, at least one of X-rays, gamma rays, energetic electrons, protons, and neutrons.

The design simulation tool 22 generates a first simulation data on a test point in the layout data LDATA based on the design simulation in step S130 (S140).

In some implementations, the design simulation tool 22 may generate transient simulation data TS_DATA corresponding to the first simulation data on the test point in the layout data LDATA, based on the design simulation in step S130.

The schematic simulation tool 21 performs schematic simulation by applying the first simulation data to the node corresponding to the test point (S150).

In some implementations, the schematic simulation tool 21 may apply transient simulation data TS_DATA to a node corresponding to a test point in the schematic data SDATA and verify the operation of the unit circuit. When the unit circuit is the latch circuit, the schematic simulation tool 21 may verify the latch operation of the unit latch circuit.

The schematic simulation tool 21 checks whether a fail operation of the unit circuit occurs to generate the second simulation data (S160).

In some implementations, the schematic simulation tool 21 may generate schematic simulation data SSIM_DATA, which is the second simulation data, based on the schematic simulation in step S150. In some implementations, schematic simulation data SSIM_DATA may include information on whether a unit circuit is in fail operation.

In some implementations, when the unit circuit is a latch circuit, the schematic simulation tool 21 may generate the schematic simulation data SSIM_DATA according to a bit flip of the unit latch circuit during schematic simulation.

In some implementations, the schematic simulation data SSIM_DATA may correspond to the partial region into which high-energy particles were injected in step S130. For example, if the layout data LDATA includes a plurality of partial regions, the schematic simulation tool 21 may generate a plurality of schematic simulation data SSIM_DATA corresponding to each of the plurality of partial regions.

The processor 10 checks whether design simulation by the design simulation tool 22 has been completed for the entire unit circuit for the received layout data LDATA (S170).

If the design simulation of step S130 has not been completed for the entire unit circuit, steps S130 to S170 may be repeatedly performed.

If the design simulation of step S130 has been completed for the entire unit circuit, the processor 10 calculates the cross-sectional area of the partial region causing the fail operation, based on a plurality of schematic simulation data SSIM_DATA corresponding to the second simulation data (S180).

The processor 10 calculates the failure rate of the circuit based on the type of unit circuit and the cross-sectional area according to the type of unit circuit (S190).

The processor 10 may calculate the circuit failure rate based on the type of unit circuit and the cross-sectional area according to the unit type. In some implementations, the processor 10 may calculate the failure rate of the circuit according to a pre-stored equation.

In some implementations, the processor 10 uses the failure rate of the row decoder RD to update the schematic data and the layout data when the failure rate is above a threshold rate. In some cases, updating the schematic data and layout data increases the likelihood of having a schematic and layout that will result in a lower failure rate.

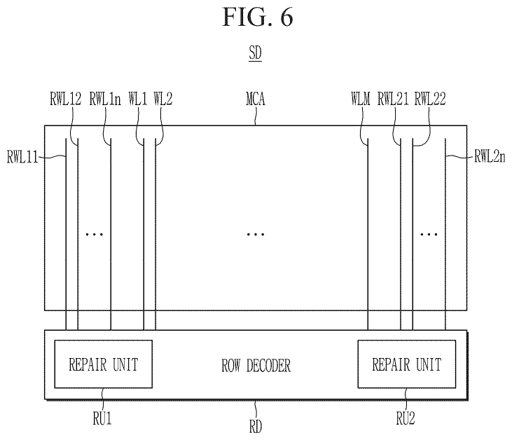

FIG. 5 is a flowchart illustrating an example of a method of predicting semiconductor device failure rate. FIGS. 6 to 14 are diagrams illustrating another example of a method of predicting semiconductor device failure rate.

Each of steps S210 to S290 of FIG. 5 may correspond to steps S110 to S190 of FIG. 4.

Referring to FIGS. 1 to 3 and 5, the schematic simulation tool 21 receives schematic data SDATA about a unit latch circuit and layout data LDATA corresponding to the schematic data SDATA. (S210).

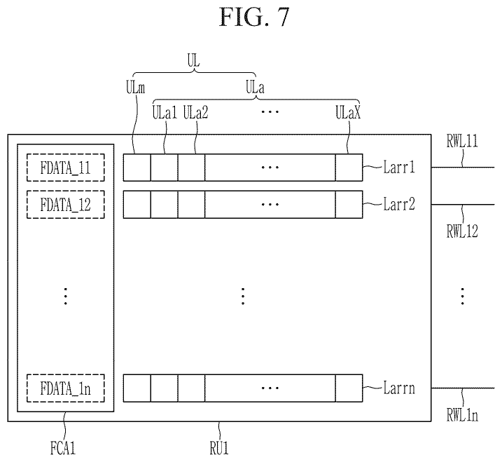

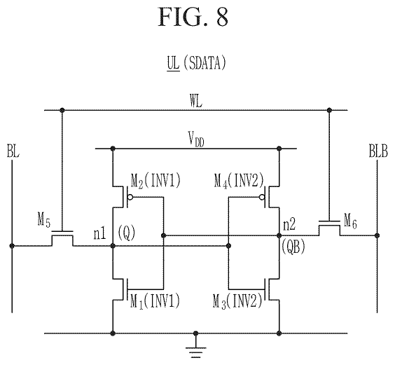

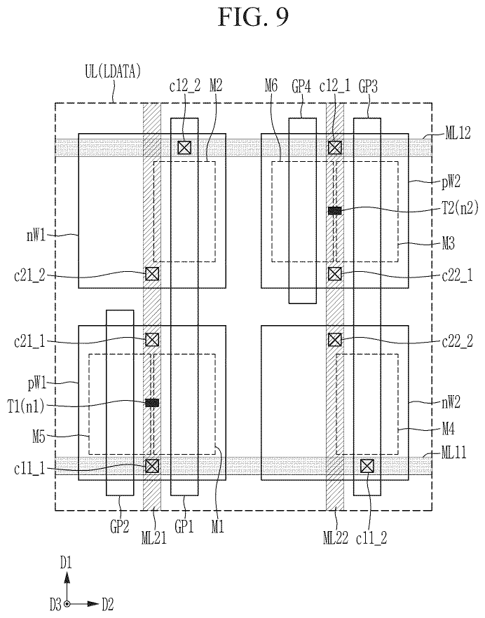

FIGS. 6 and 7 are diagrams for specifically describing a row decoder of a semiconductor device that is the target of a method of predicting the semiconductor device failure rate. FIG. 8 is an example circuit diagram of a unit latch circuit in a semiconductor device and may be a diagram visualizing schematic data SDATA. FIG. 9 is an example layout of a unit latch circuit in a semiconductor device and may be a diagram visualizing layout data LDATA.

With additional reference to FIGS. 6 to 9, a unit latch circuit UL may be included in a semiconductor device SD. The semiconductor device SD may include a memory cell array MCA and a row decoder RD. In some implementations, the semiconductor device SD may be dynamic random access memory (DRAM), such as double data rate synchronous dynamic random access memory (DDR SDRAM), low power double data rate (LPDDR) SDRAM, graphics double data rate (GDDR) SDRAM, and Rambus Dynamic Random Access Memory (RDRAM), but the semiconductor device SD is not limited thereto.

The memory cell array MCA may include a plurality of word lines WL1-WLM, a plurality of bit lines, and a plurality of memory cells positioned at the point where the word lines and bit lines cross. The semiconductor device SD may perform a read or write operation of data on a plurality of memory cells. The row decoder RD may decode the received row address and activate a word line corresponding to the row address among the plurality of word lines WL1-WLM. For example, the row decoder RD may include a plurality of word line drivers that apply a word line driving voltage to a word line corresponding to a row address.

The row decoder RD may include a first repair unit RU1 and a second repair unit RU2. The row decoder RD may activate the corresponding redundancy word line among the plurality of redundancy word lines RWL11-RWL1n and RWL11-RWL1n by the repair operation of the first repair unit RU1 and the second repair unit RU2. Hereinafter, focusing on the first repair unit RU1 and a plurality of first redundancy word lines RWL11-RWL1n, the first and second repair units RU1 and RU2 and a plurality of redundancy word lines RWL11-RWL1n and RWL11-RWL1n in the row decoder RD will be described.

The description of the first repair unit RU1 and the plurality of first redundancy word lines RWL11-RWL1n applies to the second repair unit RU2 and the plurality of second redundancy word lines RWL21-RWL2n.

The first repair unit RU1 may include a first fuse cell array FCA1 and a plurality of latch circuits. In some implementations, the first repair unit RU1 may include a plurality of latch circuits in the form of a plurality of latch arrays Larr1-Larrn.

In some implementations, the first fuse cell array FCA1 may include a one-time programmable (OTP) device. The first fuse cell array FCA1 may store first fuse data FDATA_11-FDATA_1n by performing e-fusing and anti-fusing operations on the OTP device. The first fuse data FDATA_11-FDATA_1n may include row address information about defective cells in the memory cell array MCA. The first fuse data FDATA_11-FDATA_1n may be stored non-volatilely in an anti-fusing manner by utilizing the oxide breakdown characteristics of the anti-fuse cell included in the first fuse cell array FCA1.

Each of the first fuse data FDATA_11-FDATA_1n may correspond to a plurality of latch arrays Larr1-Larrn. Based on the operation of the first repair unit RU1, the first fuse data FDATA_11-FDATA_1n may be latched to a plurality of corresponding latch arrays Larr1-Larrn. For example, when the semiconductor device SD is boot-on and the first repair unit RU1 operates, a 1_1 fuse data FDATA_11 may be latched corresponding to the first latch array Larr1, and a 1_nth fuse data FDATA_1n may be latched corresponding to the nth latch array Larrn, but the correspondence relationship is an example and is not limited thereto. In some implementations, the first fuse data FDATA_11-FDATA_1n may be latched in a plurality of latch arrays Larr1-Larrn during the operation of the first repair unit RU1.

The first repair unit RU1 may perform a repair operation in row address units based on the latch operation for the first fuse data FDATA_11-FDATA_1n of the plurality of latch arrays Larr1-Larrn. When the row address for the defective cell is input after the repair operation, the first repair unit RU1 activates the redundancy decoder in the row decoder RD.

The activated redundancy decoder disables the existing decoder for the row address of the defective cell and provides a driving voltage to one redundancy word line among the plurality of first redundancy word lines RWL11-RWL1n to replace the word line of the defective cell. If the latch operation of the plurality of latch arrays Larr1-Larrn fails, a data error in row address units may occur in the memory cell array MCA of the semiconductor device SD. In some implementations, the redundancy decoder and the first fuse cell array FCA1 may be implemented as external devices separate from the row decoder RD.

In some implementations, the plurality of latch arrays Larr1-Larrn may be configured as a unit latch circuit UL. A plurality of latch arrays Larr1-Larrn may latch data in units of 1-bit through the unit latch circuit UL.

Hereinafter, a plurality of latch arrays Lrr1-Larrn will be described, focusing on the first latch array Larr1. The description of the first latch array Larr1 may be applied to the plurality of latch arrays Larr1-Larrn. The first latch array Larr1 may include a master latch circuit ULm and a plurality of address latch circuits ULa.

In some implementations, the master latch circuit ULm may latch whether the first latch array Larr1 is used in the form of 1-bit data. If the first latch array Larr1 is used, the plurality of address latch circuits Ula may latch one of the first fuse data FDATA_11-FDATA_1n.

The plurality of address latch circuits ULa may include first to X^{th} address latch circuits ULa1-ULaX. If the Latch array Larr1 is used, each of the first to X address latch circuits ULa1-ULaX may latch the bit value of each bit position in the corresponding fuse data. In some implementations, X may equal the number of bits of fuse data.

For example, when the first latch array Larr1 is in use, the master latch circuit ULm may latch a logical high, e.g., binary number 1, and the plurality of address latch circuits ULa may latch the corresponding 1_1 fuse data FDATA_11. If the first latch array Larr1 is not in use, the master latch circuit ULm may latch a logical low, e.g., binary number 0, and the plurality of address latch circuits ULa may not perform a latch operation.

With additional reference to FIG. 8, the unit latch circuit UL may include first and second inverters INV1 and INV2 and fifth and sixth transistors M5 and M6. The first inverter INV1 may include first and second transistors M1 and M2, and the second inverter INV2 may include third and fourth transistors M3 and M4. The first transistor M1, the third transistor M3, and the fifth and sixth transistors M5 and M6 may be NMOS transistors, and the second transistor M2 and the fourth transistor M4 may be PMOS transistors.

The first inverter INV1 may include an input terminal connected to a second node n2 and an output terminal connected to a first node n1. The second inverter INV2 may include an input terminal connected to the first node n1 and an output terminal connected to the second node n2.

For example, in FIG. 8, the unit latch circuit UL is implemented as a SRAM memory cell including a total of 6 transistors, but the unit latch circuit UL is not limited thereto and may be modified/changed to various types of latch circuits that perform the operations described below.

The first and second inverters INV1 and INV2 may latch data on the first and second nodes n1 and n2. The first and second inverters INV1 and INV2 may be connected between the first and second nodes n1 and n2. The first inverter INV1 may form data Q on the first node n1 by inverting the logic value of data QB on the second node n2. The second inverter INV2 may form data Q on the first node n1 by inverting the logic value of data QB on the second node n2.

Accordingly, data Q may be latched on the first node n1 and data QB may be latched on the second node N2. The logic value of data Q and the logic value of data QB may be complementary. The unit latch circuit UL may store at least a portion of the fuse data of the first fuse cell array FCA1 through the latch operation of the first and second inverters INV1 and INV2. In some implementations, the first and second nodes n1 and n2 may be output nodes of the unit latch circuit UL.

Each of the fifth and sixth transistors M5 and M6 may be a switch transistor for a switching operation. In some implementations, the fifth and sixth transistors M5 and M6 may be referred to as access transistors. Gate terminals of the fifth and sixth transistors M5 and M6 may receive data having a specific logic level through the word line WL. The fifth transistor M5 may be connected between the bit line BL and the first node n1. The fifth transistor M5 may transfer the latched data Q of the first node n1, which is an output node, to the bit line BL.

The sixth transistor M6 may be connected between a bit line BLB and the second node n2. The sixth transistor M6 may transfer the latched data QB of the second node n2, which is an output node, to the bit line BLB.

Referring to FIG. 9, the unit latch circuit UL may be formed on a substrate, the substrate may be doped with P-type impurities, and may include a semiconductor such as silicon (Si) or germanium (Ge), or Group III-V compounds such as GaAs, AlGaAs, InAs, InGaAs, InSb, GaSb, InGaSb, InP, GaP, InGaP, InN, GaN, InGaN, or the like. In some implementations, the substrate may be a silicon-on-insulator (SOI) substrate or a germanium-on-insulator (GOI) substrate.

The unit latch circuit UL may include first and second positive- (P-) wells pW1 and pW2, first and second negative- (N-) wells nW1 and nW2, first to fourth gate patterns GP1-GP4, a first connecting wires ML11 and ML12, and second connecting wires ML21 and ML22.

The first and second P-wells pW1 and pW2, and the first and second N-wells nW1 and nW2 may be disposed to non-overlap each other in the third direction D3 on the substrate. The unit latch circuit UL may include first and second P-wells pW1 and pW2 and first and second N-wells nW1 and nW2. The first and second P-wells pW1 and pW2 and the first and second N-wells nW1 and nW2 may be referred to as active regions. In the drawings, the first and second P-wells pW1 and pW2 are shown as being separated from the substrate, but the first and second P-wells pW1 and pW2 may be regions doped with P-type impurities, like the substrate.

The first to fourth gate patterns GP1-GP4 may extend in the first direction D1. The first to fourth gate patterns GP1-GP4 are conductive electrode patterns and may include a single layer of TiN, TiAlN, and TiAlC or a combination of the above single layers, but the first to fourth gate patterns GP1-GP4 are not limited thereto.

The first gate pattern GP1 may be disposed to overlap at least a portion of the first P-well pW1 and at least a portion of the first N-well nW1 in the third direction D3. The second gate pattern GP2 may be disposed to overlap at least a portion of the first P-well pW1 in the third direction D3. The third gate pattern GP3 may be disposed to overlap at least a portion of the second P-well pW2 and at least a portion of the second N-well nW2 in the third direction D3. The fourth gate pattern GP4 may be disposed to overlap at least a portion of the second P-well pW2 in the third direction D3.

The first gate pattern GP1 and the first P-well pW1 may form the first transistor M1 of the first inverter INV1. The first gate pattern GP1 and the first N-well nW1 may form the second transistor M2 of the first inverter INV1. The third gate pattern GP3 and the second P-well pW2 may form the third transistor M3 of the second inverter INV2. The third gate pattern GP3 and the second N-well nW2 may form the fourth transistor M4 of the second inverter INV2. The second gate pattern GP2 and the first P-well pW1 may form the fifth transistor M1. The fourth gate pattern GP4 and the second P-well pW2 may form the sixth transistor M6.

A source/drain region in which a region doped with an N-type impurity may be disposed in at least some regions of the first and second P-wells pW1 and pW2, and source/drain region in which a region doped with a P-type impurity may be disposed in at least some regions of the first and second N-wells nW1 and nW2. In the implementations illustrated herein, the phrase source/drain region may be understood to mean a source region and/or a drain region of a transistor.

A first test point T1 on the first P-well pW1 formed between the first gate pattern GP1 and the second gate pattern GP2 may correspond to the first node n1, and a second test point T2 on the second P-well pW2 formed between the third gate pattern GP3 and the fourth gate pattern GP4 may correspond to the second node n2.

The first connecting wires ML11 and ML12 are conductive patterns that extend in the second direction D2 and may connect the gate pattern and the semiconductor layer. A connecting wire ML11 may connect the third gate pattern GP3 and the first P-well pW1 through contacts c11_1 and c11_2 extending in the third direction D3. A connecting wire ML12 may connect the first gate pattern GP1 and the second P-well pW2 through contacts c12_1 and c12_2 extending in the third direction D3.

The second connecting wires ML21 and ML12 are conductive patterns that extend in the first direction D1 and may connect the semiconductor layers. A connecting wire ML21 extends in the first direction D1 between the first gate pattern GP1 and the second gate pattern GP2 and may connect the first P-well pW1 and the first N-well nW1 through contacts c21_1 and c21_2 extending in the third direction D3. A connecting wire ML22 extends in the first direction D1 between the third gate pattern GP3 and the fourth gate pattern GP4 and may connect the second P-well pW2 and the second N-well nW2 through contacts c22_1 and c22_2 extending in the third direction D3.

The first connecting wires ML11 and ML12 and the second connecting wires ML21 and ML12 may be disposed at different heights from the substrate in the third direction D3. In some implementations, the second connecting wires ML21 and ML12 may be disposed higher than the second connecting wires ML21 and ML12 in the third direction D3 from the substrate.

An insulating layer may be disposed between material layers, such as a conductive layer and a semiconductor layer. In addition, the layout shown in FIG. 9 is an example layout corresponding to the unit latch circuit UL of FIG. 8, and patterns of material layers, e.g., a conductive layer, a semiconductor layer, and an insulating layer, and the arrangement of these patterns may vary.

The schematic simulation tool 21 generates a netlist NL based on schematic data SDATA and layout data LDATA (S220).

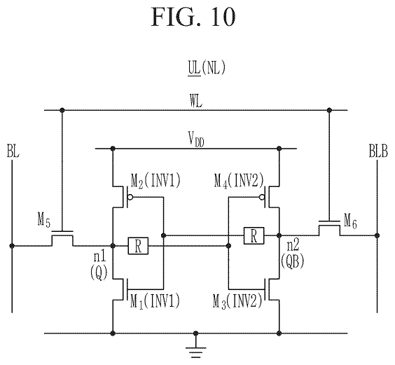

Referring to FIG. 10, the schematic simulation tool 21 may generate a netlist NL reflecting layout data LDATA based on schematic data SDATA. The netlist NL may reflect conductive layers such as the first connecting wires ML11 and ML12 and the second connecting wires ML21 and ML22 of FIG. 9.

When compared to the schematic data SDATA of FIG. 8, the netlist NL may further include a resistor R1 disposed between the first node n1 and the gate terminals of the third and fourth transistors M3 and M4, and a resistor R2 disposed between the second node n2 and the gate terminals of the first and second transistors M1 and M2. In some implementations, the netlist NL may further include capacitors corresponding to the conductive layer and the insulating layer, such as the first connecting wires ML11 and ML12 and the second connecting wires ML21 and ML22, compared to the schematic data SDATA of FIG. 8.

The circuit for schematic data SDATA and the circuit for the netlist NL may have some differences in resistive and capacitive components, but the circuit for schematic data SDATA and the circuit for the netlist NL may be the same.

The design simulation tool 22 performs design simulation on a partial region in the unit latch circuit UL based on layout data LDATA (S230).

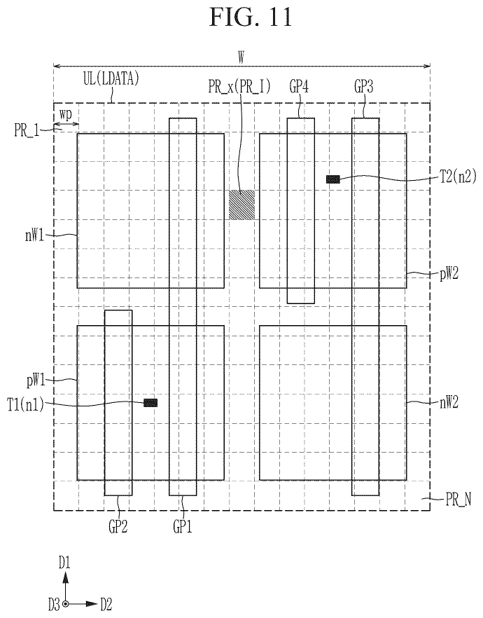

Referring additionally to FIG. 11, the layout data LDATA for the unit latch circuit UL may include distinct first to Nth partial regions PR_1-PR_N. The N is an integer of 2 or more, and N may be 100 to 1000, preferably 250 to 1000.

The ratio of the partial width (wp) of the first to Nth partial regions PR_1-PR_N to the entire width (W) of the unit latch circuit UL may be 0.032 to 0.1 and preferably may be 0.032 to 0.063.

The design simulation tool 22 may set a x^{th} partial region PR_x, which is one of the first to Nth partial regions PR_1-PR_N, as a high-energy particle injection region PR_I. The design simulation tool 22 may use the design simulation module 221 to perform an operation simulation corresponding to the injection of high-energy particles into the high-energy particle injection region PR_I in the layout data LDATA. The number x may be an integer within the range of 1 to N.

The design simulation tool 22 generates the first simulation data on the test points T1 and T2 in the layout data LDATA based on the design simulation in step S240 (S240).

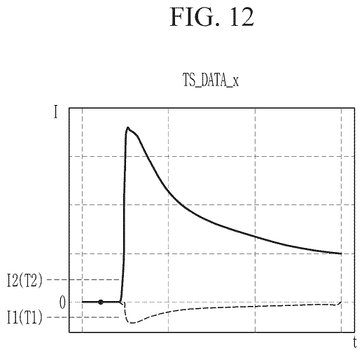

Referring to FIG. 12, the design simulation tool 22 may generate transient simulation data TS_DATA from a first noise current I1 detected at the first test point T1 corresponding to the first node n1 of FIG. 10 and a second noise current 12 detected at the second test point T2 corresponding to the second node n2.

The design simulation tool 22 may generate the detected first noise current I1 and the second noise current 12 as an x^{th} transient simulation data TS_DATA_x, in response to the injection of high-energy particles into the x^{th} partial region PR_x.

The schematic simulation tool 21 applies transient simulation data to the output node corresponding to the test point to perform schematic simulation (S250).

The schematic simulation tool 21 may perform schematic simulation by applying the x^{th} transient simulation data TS_DATA_x to the first and second nodes n1 and n2 corresponding to the first and second test points T1 and T2.

The schematic simulation tool 21 checks whether a bit flip occurs in the unit latch circuit UL to generate schematic simulation data SSIM_DATA (S260).

Referring to FIG. 12, while performing the schematic simulation in step S250, the schematic simulation tool 21 may check first and second node voltages V1 and V2 of the first and second nodes n1 and n2 corresponding to logic values latched at each of the first and second nodes n1 and n2. Depending on whether the first and second node voltages V1 and V2 are flipped, the schematic simulation tool 21 may generate schematic simulation data SSIM_DATA.

The schematic simulation data SSIM_DATA may correspond to the position of the high-energy particle injection region PR_I where high-energy particles are injected in step S230. For example, a schematic simulation may be performed based on the x^{th} transient simulation data TS_DATA_x generated by setting the x^{th} partial region PR_x to the high-energy particle injection region PR_I.

The schematic simulation tool 21 may check whether a bit flip of the unit latch circuit UL occurs according to the application of the x^{th} transient simulation data TS_DATA_x. The schematic simulation tool 21 generates the x^{th} schematic simulation data SSIM_DATA_x depending on the occurrence of the bit flip.

The processor 10 checks whether the design simulation by the design simulation tool 22 has been completed for the entire unit latch circuit UL (S270).

If the design simulation of step S130 has not been completed for the entire unit latch circuit UL, steps S130 to S170 may be repeatedly performed.

The processor 10 may execute the design simulation tool 22 and the schematic simulation tool 21 so that steps S130 to S170 are performed for each of the first to Nth partial regions PR_1-PR_N.

If the design simulation has been completed for the entire unit latch circuit UL, the processor 10 calculates the cross-sectional area of the partial area causing the bit flip based on a plurality of schematic simulation data SSIM_DATA (S280).

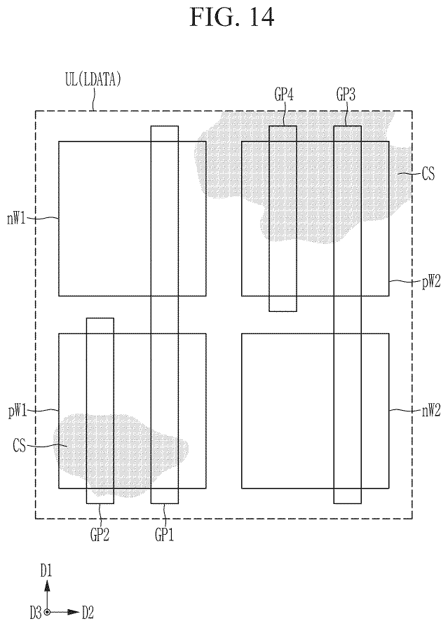

Referring to FIG. 14, the processor 10 may calculate a cross-sectional area CS for the region causing the bit flip in step S250 among the first to Nth partial regions PR_1-PR_N of the unit latch circuit UL, based on a plurality of schematic simulation data SSIM_DATA.

In some implementations, the processor 10 may calculate the cross-sectional area ratio, which is the ratio of the total area of the unit latch circuit UL to the cross-sectional area CS.

The processor 10 calculates the failure rate of the row decoder RD based on the type of the unit latch circuit UL and the cross-sectional area according to the type of the unit latch circuit UL (S290). In some implementations, the processor 10 uses the failure rate of the row decoder RD to update the schematic data SDATA and the layout data LDATA when the failure rate is above a threshold rate. In some cases, updating the schematic data and layout data increases the likelihood of having a schematic and layout that will result in a lower failure rate.

Referring to FIG. 7, the unit latch circuit UL may include the master latch circuit ULm and a plurality of address latch circuits ULa. Additionally, the master latch circuit ULm may be classified into types depending on whether a latch array including the master latch circuit ULm is used.

In some implementations, the master latch circuit ULm may be classified into a master latch circuit in which the latch array is in use and a master latch circuit in which the latch array is not in use. In some implementations, the utilization rate of the plurality of latch arrays Larr1-Larrn may be calculated based on the ratio of the number of the latch arrays in use and the number of the plurality of latch arrays Larr1-Larrn.

Therefore, the processor 10 may calculate the failure rate of the row decoder RD based on at least one of the cross-sectional area and the cross-sectional area ratio of the unit latch circuit UL corresponding to the master latch circuit ULm in use by the latch array, at least one of the cross-sectional area and the cross-sectional area ratio of the unit latch circuit UL for the master latch circuit ULm not in use by the latch array, and at least one of the cross-sectional area and cross-sectional area ratio of the unit latch circuit UL for the plurality of address latch circuits ULa.

In some implementations, the processor 10 may calculate the failure rate of the row decoder RD in the form of a single event functional interrupt (SEFI) according to Equation 1 below.

$$SEFI = A \times N [ R ( \frac{{N}_{m}}{{N}_{m} + {N}_{a}} {σ}_{m 0} + \frac{{N}_{a}}{{N}_{m} + {N}_{a}} {σ}_{a} ) + ( 1 - R ) ( \frac{{N}_{m}}{{N}_{m} + {N}_{a}} \times {σ}_{m 1} ) ] \qquad ( Equation 1 )$$

The SEFI is the failure rate of the row decoder RD and may be represented in failure in time (FIT) units, the A is a predetermined constant, the N is the number of the unit latch circuits UL in the plurality of latch arrays Larr1-Larrn, the R is the utilization rate for the plurality of latch arrays Larr1-Larrn, the Nₘ is the number of the master latch circuits ULm in the row decoder RD, the Nₐ is the number of address latch circuits ULm in the row decoder RD, the σₘ₀ is the cross-sectional area ratio to the unit latch circuit UL of the master latch circuit ULm in which the latch array is in use, the σₐ. is the cross-sectional area ratio to the unit latch circuit UL of the master latch circuit ULm in which the latch array is not in use, and the σₘ₁ is the cross-sectional area ratio of the unit latch circuit UL to the plurality of address latch circuits ULa.

The method of predicting the semiconductor device failure rate may be applied to a repair unit in a column decoder that is connected to the memory cell array (MCA) and performs a repair operation. The description of FIGS. 5 to 14 may be applied to the unit latch circuit in the column decoder.

The method of predicting the semiconductor device failure rate may precisely and easily predict the failure rate of a semiconductor device using heterogeneous simulation tools. In particular, the method of predicting the semiconductor device failure rate may precisely and easily predict the failure rate for soft errors caused by high-energy particles.

The method of predicting the semiconductor device failure rate enables predictions of the failure rate of an entire functional block circuit by using an area ratio according to the type of unit circuit in one functional block circuit. The method of predicting the semiconductor device failure rate enables predictions of the failure rate of a word line unit replacement operation using a cross-sectional area ratio according to the type of unit latch circuit causing the failure. By the method of predicting the semiconductor device failure rate, checking the design suitability of layout data LDATA considering high-energy particles such as space radiation is possible.

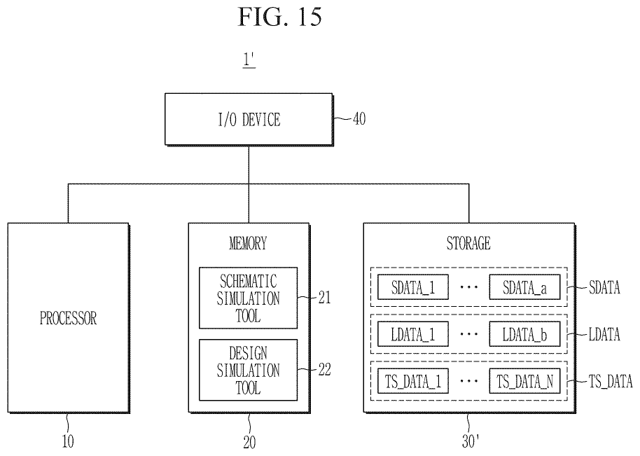

FIG. 15 is a block diagram illustrating an example of an electronic device. An electronic device 1′ of FIG. 15 may correspond to the electronic device 1 of FIG. 1. To be concise, the description will focus on the differences between the electronic device 1′ and the electronic device 1 and repeated description will be omitted.

A storage device 30′ of the electronic device 1′ may store first to Nth transient simulation data TS_DATA_1-TS_DATA_N in addition to schematic data SDATA and layout data LDATA.

In some implementations, the first to Nth transient simulation data TS_DATA_1-TS_DATA_N may be generated by operation simulation of the design simulation tool 22. The operation simulation may include injecting high-energy particles into a partial region in the layout data LDATA.

In some implementations, the first to Nth transient simulation data TS_DATA_1-TS_DATA_N may include transient information of the noise current at one point in the operation simulation.

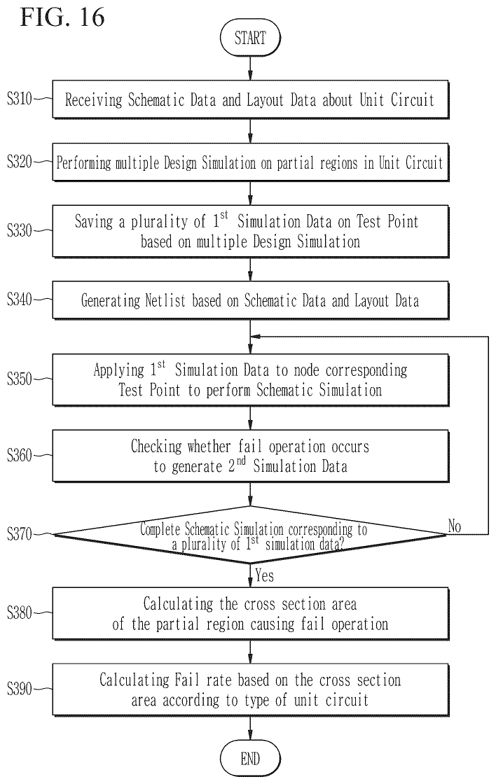

FIG. 16 is a flowchart illustrating an example of a method of predicting semiconductor device failure rate. The method of predicting semiconductor device failure rate of FIG. 16 may correspond to the method of predicting semiconductor device failure rate of FIG. 4. To be concise, the following description will focus on differences from the method of predicting the semiconductor device failure rate of FIG. 4 and repeated description will be omitted.

Referring to FIGS. 4, 15, and 16, the schematic simulation tool 21 receives schematic data SDATA and layout data LDATA corresponding to the schematic data SDATA (S310).

Step S310 may correspond to step S110. The schematic simulation tool 21 may receive schematic data SDATA stored in the storage device 30′ and layout data LDATA corresponding to the schematic data SDATA. The design simulation tool 22 may receive layout data LDATA input to the schematic simulation tool 21.

The design simulation tool 22 performs a plurality of design simulations on a plurality of partial regions based on layout data LDATA (S320).

Step S320 may correspond to step S130 of FIG. 4. In some implementations, the design simulation tool 22 may use the design simulation module 221 to perform a plurality of operation simulations corresponding to the injection of high-energy particles for a plurality of partial regions in the layout data LDATA.

The design simulation tool 22 stores a plurality of first simulation data on test points in the layout data LDATA based on the design simulation in step S320 (S330).

Step S330 may correspond to step S140 of FIG. 4. In some implementations, the design simulation tool 22 may generate a plurality of transient simulation data TS_DATA corresponding to the first simulation data on the test point in the layout data LDATA based on the design simulation in step S320.

The design simulation tool 22 may store a plurality of generated transient simulation data TS_DATA in the storage device 30′. For example, the plurality of transient simulation data TS_DATA may include first to Nth transient simulation data TS_DATA_1-TS_DATA_N. In some implementations, the first to Nth transient simulation data TS_DATA_1-TS_DATA_N may be generated based on design simulation for the first to Nth partial regions PR_1-PR_N of FIG. 11.

The schematic simulation tool 21 generates a netlist based on schematic data SDATA and layout data LDATA (S340).

Step S340 may correspond to step S120 of FIG. 4. In some implementations, the schematic simulation tool 21 may receive schematic data SDATA stored in the storage device 30′ and layout data LDATA corresponding to the schematic data SDATA at step S340 instead of step S310.

In some implementations, the netlist NL may reflect the parasitic resistance and parasitic capacitance of the connecting wires in the layout data LDATA based on the schematic data SDATA.

The schematic simulation tool 21 applies the first simulation data to the node corresponding to the test point to perform schematic simulation (S350).

Step S350 may correspond to step S150 of FIG. 4. In some implementations, the schematic simulation tool 21 may apply transient simulation data TS_DATA to a node corresponding to a test point in the schematic data SDATA and verify the operation of the unit circuit.

The schematic simulation tool 21 checks whether a fail operation of the unit circuit occurs to generate the second simulation data (S360).

Step S360 may correspond to step S160 of FIG. 4. In some implementations, the schematic simulation tool 21 may generate schematic simulation data SSIM_DATA, which is the second simulation data, based on the schematic simulation in step S350. In some implementations, schematic simulation data SSIM_DATA may include information on whether a unit circuit is in fail operation.

In some implementations, the schematic simulation data SSIM_DATA may correspond to one of the first to Nth transient simulation data TS_DATA_1-TS_DATA_N stored in step S330. For example, the schematic simulation tool 21 may generate a plurality of schematic simulation data SSIM_DATA corresponding to each of the first to Nth transient simulation data TS_DATA_1-TS_DATA_N.

The processor 10 checks whether the schematic simulation by the schematic simulation tool 21 has been completed for the first to Nth transient simulation data TS_DATA_1-TS_DATA_N (S370).

Step S370 may correspond to step S170 of FIG. 4. In response to the schematic simulation of step S350 not being completed for all of the first to Nth transient simulation data TS_DATA_1-TS_DATA_N, steps S350 to S370 may be repeatedly performed.

In response to the schematic simulation of step S350 being completed for all of the first to Nth transient simulation data TS_DATA_1-TS_DATA_N, the processor 10 calculates the cross-sectional area of the partial region causing the fail operation, based on the plurality of schematic simulation data SSIM_DATA corresponding to the second simulation data (S380).

The processor 10 calculates the failure rate of the circuit based on the type of unit circuit and the cross-sectional area according to the type of the unit circuit (S390).

The processor 10 may calculate the circuit failure rate based on the type of unit circuit and the cross-sectional area according to the unit type. In some implementations, the processor 10 may calculate the failure rate of the circuit according to a pre-stored equation.

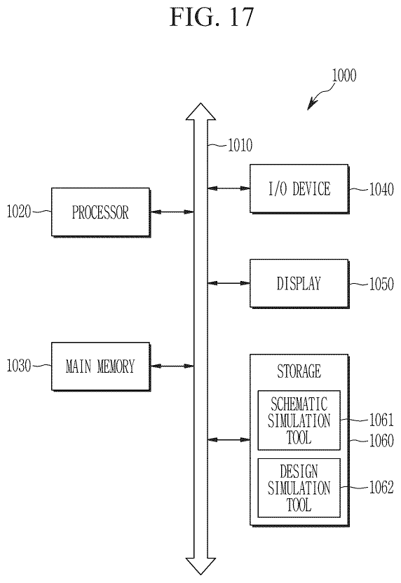

FIG. 17 is a block diagram illustrating an example of a computing system that performs a method of predicting semiconductor device failure rate.

The computing system 1000 may include a system bus 1010, a processor 1020, a main memory 1030, an input/output device 1040, a display device 1050, and a storage device 1060. The processor 1020 may be configured as a single core or multi-core. The input/output device 1040 may be a keyboard, mouse, printer, or the like. The main memory 1030 may be volatile memory such as DRAM or SRAM. The display device 1050 may include a display device such as an LCD, LED display, or OLED display. The storage device 1060 may be non-volatile memory, such as a hard disc drive (HDD) or solid-state drive (SSD).

The storage device 1060 may store program codes (e.g., computer-readable program codes) for performing the method of predicting the semiconductor device failure rate as in the above-described embodiments. The program code may be loaded into the main memory 1030 and executed by the processor 1020, and the failure rate, which is the predicted result of the execution result, may be output to the input/output device 1040 or the display device 1050.

In some implementations, the storage device 1060 may store a schematic simulation tool 1061, a design simulation tool 1062, and a predicted failure rate. The program codes may include codes for calculating and predicting failure rates for soft errors caused by high-energy particles, by using schematic data and layout data.

The computing system 1000 may precisely predict the semiconductor device failure rate based on schematic data and layout data. Additionally, the computing system 1000 may check design suitability of layout data LDATA considering high-energy particles such as cosmic radiation.

The method of predicting semiconductor device failure rate of the present disclosure may be implemented in the form of program instructions that can be performed through various computer means and recorded on a computer-readable medium. Additionally, an implementation of the present disclosure may be a computer-readable recording medium on which one or more programs including instructions for executing a method of predicting semiconductor device failure rate are recorded.

The computer-readable medium may include, alone or in combination with program instructions, data files, data structures, and the like. The program instructions recorded on the media may be those specially designed and constructed, or they may be of the kind well-known and available to those having skill in the computer software arts. Examples of computer-readable media include magnetic media such as hard disks, floppy disks, and magnetic tape; optical media such as CD ROM discs and DVDs; magneto-optical media such as optical discs; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter.

Here, the machine-readable storage medium may be provided in the form of a non-transitory storage medium. Here, when a storage medium is referred to as ‘non-transitory’, it can be understood that the storage medium is a tangible and does not include a signal (for example, electromagnetic waves), and rather that data is semi-permanently or temporarily stored in the storage medium. For example, a ‘non-transitory storage medium’ may include a buffer where data is temporarily stored.

In some implementations, the methods according to the various examples disclosed herein may be provided in a computer program product. The computer program product may be traded between a seller and a buyer as a product. The computer program product may be distributed in the form of a machine-readable storage medium (e.g., compact disc read only memory (CD-ROM)), or may be distributed directly between two user devices (e.g., smartphones) through an application store (e.g., Play Store™), or online (e.g., downloaded or uploaded). In the case of online distribution, at least a portion of the computer program product (e.g., a downloadable app) may be stored at least semi-permanently or may be temporarily generated in a machine-readable storage medium, such as a memory of a server of a manufacturer, a server of an application store, or a relay server.

The drawings and description are to be regarded as illustrative in nature and not restrictive. Like reference numerals designate like elements throughout the specification.

In addition, unless explicitly described to the contrary, the word “comprise”, and variations such as “comprises” or “comprising”, will be understood to imply the inclusion of stated elements but not the exclusion of any other elements.

Additionally, specific numbers described in a claim, even if explicitly recited within the claim, should not be construed as limiting the specific number in claims where such citation does not exist. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

Furthermore, in those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In some implementations, ‘a module’, ‘a unit’, or ‘a part’ perform at least one function or operation, and may be realized as hardware, such as a processor or integrated circuit, software that is executed by a processor, or a combination thereof.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A method of predicting semiconductor device failure rate, the method comprising:
receiving schematic data for a unit circuit in a first circuit and layout data corresponding to the schematic data;
generating, by at least one processor, a netlist based on the schematic data and the layout data;
performing a first simulation on the layout data to generate first simulation data for a test point of the layout data corresponding to a first node in the netlist;
applying the first simulation data to a second simulation for the first node to generate second simulation data regarding whether the unit circuit is in fail operation; and
calculating a failure rate for the first circuit based on the second simulation data.

2. The method of predicting semiconductor device failure rate of claim 1, wherein performing the first simulation comprises performing, by a first simulation tool, the first simulation, and
wherein applying the first simulation data to a second simulation for the first comprises performing, by a second simulation tool different from the first simulation tool, the second simulation.

3. The method of predicting semiconductor device failure rate of claim 2, wherein the first simulation tool is a technology computer aided design (TCAD) simulation tool, and the second simulation tool is a simulation program with integrated circuit emphasis (SPICE) simulation tool.

4. The method of predicting semiconductor device failure rate of claim 1, wherein performing the first simulation comprises simulating injection of high-energy particles into a first partial region among a plurality of partial regions in the layout data for the unit circuit.

5. The method of predicting semiconductor device failure rate of claim 4, further comprising:
generating third simulation data for the test point by performing a third simulation, wherein performing the third simulation comprises simulating injecting high-energy particles into a second partial region different from the first partial region in the layout data; and
applying the third simulation data to a fourth simulation for the first node to generate fourth simulation data regarding whether the unit circuit fails.

6. The method of predicting semiconductor device failure rate of claim 5, further comprising:
calculating a cross-sectional area of a plurality of partial regions that generate a fail operation for the unit circuit among the plurality of partial regions, based on the second simulation data and the fourth simulation data,
wherein the failure rate is calculated based on a type of the unit circuit and the cross-sectional area.

7. The method of predicting semiconductor device failure rate of claim 5, wherein performing the third simulation occurs after performing the first simulation,
and generating the second simulation data occurs between performing the first simulation and performing the third simulation.

8. The method of predicting semiconductor device failure rate of claim 4, comprising, before calculating of the failure rate, checking for completion of simulation for the plurality of partial regions.

9. The method of predicting semiconductor device failure rate of claim 4, wherein the unit circuit is a latch circuit that latches 1-bit of data.

10. A method of predicting semiconductor device failure rate, comprising:
receiving schematic data for a unit latch circuit among a plurality of latch circuits in a row decoder for a memory cell array and layout data corresponding to the schematic data;
performing a first simulation of injecting high-energy particles into a partial region in the layout data of the unit latch circuit;
generating first simulation data for a noise current detected at a test point of the layout data corresponding to an output node of the unit latch circuit according to the first simulation;
performing a second simulation by applying the first simulation data to the output node;
generating second simulation data by checking whether a bit flip occurs in the unit latch circuit according to the second simulation;
calculating a cross-sectional area of a partial region causing a bit flip in the unit latch circuit based on the second simulation data; and
calculating a failure rate for the row decoder based on the cross-sectional area.

11. The method of predicting semiconductor device failure rate of claim 10, wherein performing the first simulation comprises simulating injection of high-energy particles into a first partial region of a plurality of partial regions that are distinct from each other,
and the high-energy particles comprise at least one of X-rays, gamma-rays, energy electrons, protons, and neutrons.

12. The method of predicting semiconductor device failure rate of claim 11, wherein the first simulation data is temporary transient data for the noise current.

13. The method of predicting semiconductor device failure rate of claim 10, wherein the output node comprises a first output node and a second output node, and
the unit latch circuit comprises (i) a first inverter including a first input terminal connected to the first output node and a first output terminal connected to the second output node and (ii) a second inverter including a second input terminal connected to the second output node and a second output terminal connected to the first output node.

14. The method of predicting semiconductor device failure rate of claim 13, wherein the layout data comprises a first test point corresponding to the first output node and a second test point corresponding to the second output node, and
the noise current comprises a first noise current detected at the first test point and a second noise current detected at the second test point.

15. The method of predicting semiconductor device failure rate of claim 10, wherein the plurality of latch circuits are part of a repair unit in the row decoder,
the plurality of latch circuits comprise a first latch array and a second latch array different from the first latch array,
the first latch array comprises a first master latch circuit and a plurality of first address latch circuits, and
the second latch array comprises a second master latch circuit and a plurality of second address latch circuits.

16. The method of predicting semiconductor device failure rate of claim 15, comprising:
latching, by the first master latch circuit, a logical high; and
latching, by the second master latch circuit, a logical low,
wherein the repair unit comprises a fuse cell array corresponding to the plurality of latch circuits and storing fuse data for a row address of a defective cell, and
the plurality of first address latch circuits latch the fuse data.

17. The method of predicting semiconductor device failure rate of claim 16, comprising, by the repair unit, applying a word line voltage to a redundancy word line based on the fuse data latched in the plurality of first address latch circuits.

18. The method of predicting semiconductor device failure rate of claim 16, wherein the unit latch circuit comprises a first unit latch circuit corresponding to the first master latch circuit, a second unit latch circuit corresponding to the second master latch circuit, and a third unit latch circuit corresponding to the plurality of first address latch circuits, and
the cross-sectional area comprises a first cross-sectional area for the first unit latch circuit, a second cross-sectional area for the second unit latch circuit, and a third cross-sectional area for the third unit latch circuit.

19. The method of predicting semiconductor device failure rate of claim 18, wherein the failure rate, single event functional interrupt (SEFI), is calculated based on
$$SEFI = A \times N [ R ( \frac{{N}_{m}}{{N}_{m} + {N}_{a}} {σ}_{m 0} + \frac{{N}_{a}}{{N}_{m} + {N}_{a}} {σ}_{a} ) + ( 1 - R ) ( \frac{{N}_{m}}{{N}_{m} + {N}_{a}} \times {σ}_{m 1} ) ] ,$$
wherein A is a predetermined process coefficient, N is the number of the plurality of latch circuits, R is a utilization rate of the latch array in the plurality of latch circuits, Nₘ is a number of master latch circuits in the latch array, Nₐ is a number of address latch circuits in the latch array, σₘ₀ is a ratio of the cross-sectional area of the first unit latch circuit to the first cross-sectional area, σₘ₁ is a ratio of the cross-sectional area of the second unit latch circuit to the second cross-sectional area, and σₐ is a ratio of the cross-sectional area of the third unit latch circuit to the third cross-sectional area.

20. An electronic device, comprising:
a user interface device;
a processor; and
a memory configured to store instructions executable by the processor,
wherein the processor is further configured to execute the instructions to receive schematic data for a first circuit and layout data corresponding to the schematic data,
perform a first simulation on a test point of the layout data corresponding to a node in the first circuit to store first simulation data,
apply the first simulation data to a second simulation of the schematic data to generate a second simulation data regarding whether the second simulation fails, and
calculate a failure rate for the first circuit based on the second simulation data.
